(19) United States
(12) Patent Application Publication
(10) Pub. No.: US 2006/0002424 A1
(43) Pub. Date: Jan. 5, 2006

(54) Multiple instances of the same type of processing module within a layered communication stack

(76) Inventor: Srinivas Gadde, Austin, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/884,669

(22) Filed: Jul. 2, 2004

(51) Int. Cl. H04L 1/00; H04J 3/16; G01R 31/08; G08C 15/00; H04L 12/26; G06F 11/00; H04J 3/14; H04J 1/16; H04J 3/22

(52) U.S. Cl. 370/469

(57) ABSTRACT

Greater throughput for a particular communication layer protocol is achieved in a multiprocessor host by having different instances of the same process running in parallel as separate modules associated with different processor, including at least one instance with functionality for Control messages and other instances with functionality for Data messages. The Control message functionality may be included in a Master module and the Data message functionality may be included in Slave modules; alternatively both functionalities may be included in the same modules arranged in a Distributed Peer configuration.

### BACKGROUND

The present invention is generally related to the processing of multiple streams of messages, and more specifically related to a layered stack of modules for communicating those messages to respective applications.

Communication of application data and communication control information between networked computers is typically handled in a layered fashion, with each layer responsible for a different aspect of the information transfer and providing a foundation for more application specific tasks performed by higher levels. Within each of the networked computers or other network nodes (such as network controllers, switches and routers), the involved layers form a “communicate stack”, which may include multiple hardware and/or software modules at a given level, each responsible for a different “protocol”. Between the various network-oriented hardware which forms the lowermost Physical network layer and the various application-oriented software which forms the Application layer there is typically provided a Network communication layer, which provides a means of identifying physical network nodes and routing a message from a particular source node to a particular destination node. In the specific case of the Internet and internet-compatible networks the Network layer includes the Internet Protocol (or simply “IP”). The actual content of the message typically includes data that is associated not just to a particular node, but also to a particular ongoing process or endpoint associated with that node. Thus, the Network layer is typically supplemented by a Transport layer which defines an end to end connection between a particular application process at the source node and a corresponding process at the destination node.

In the case of the Internet, a Transport layer can utilize several different protocols, the best known of which is the Transmission Control Protocol (or simply “TCP”). TCP provides not only a means of associating individual processes at a particular node into respective “ports”, but also a means of reliably transporting a stream of information messages (“packets”) over an underlying IP layer from a source endpoint to a destination endpoint, with each TCP/IP logical “connection” being defined by a pair of source and destination transport addresses each consisting of an associated IP address and port number. Stream Control Transmission Protocol (or “SCTP”) is a more advanced transmission protocol which is capable of transmitting multiple related streams between a source port at the transmitting node and a destination port at the receiving node using multiple IP addresses at one or both nodes to thereby define a single logical SCTP “association”. Other Transport layer protocols include UDP (User Datagram Protocol). Unlike TCP, UDP provides very few error recovery services, offering instead a direct way to send and receive datagrams over an IP network.

Datagrams flow through the IP layer in two directions: from the network up to user processes and from user processes down to the network. Using this orientation, IP is layered above the network interface drivers and below the transport protocols such as UDP and TCP. ICMP (Internet Control Message Protocol) and RAWIP (“Raw” Internet Protocol) share attributes with both the Network layer and/or the Transport layer, and may be classified as part of either or both. The PING command, for example, uses ICMP to test an Internet connection.

Since the received messages typically arrive at multiple terminal nodes in no particular order from multiple sources, it is convenient to route them all to a common Network layer processing module which performs any required Network layer basic communication processing, such as Defragmentation, verification of Header integrity, processing of any contained Network layer Control messages, and forwarding of any contained Data to an associated Transport layer processing module responsible for the Transport Protocol designated in the message Header. Analogous basic communication functionality is also performed on the received Network layer Data by the responsible Transport layer processing module, as well as any additional functionality provided by the designated Transport protocol to ensure reliable end to end communication for the Application layer processes. In particular, the Transport layer processing module associated with a particular Transport protocol will typically provide additional mechanisms at each end of an IP connection for ensuring the integrity of the received Data and for reorganizing the individual received messages into one or more data streams and for communicating each data stream in the proper sequence to its intended Application layer process.

### SUMMARY

In accordance with one embodiment of the present invention, greater throughput for a particular communication layer protocol is achieved in a multiprocessor host by having different instances of the same type of process running in parallel as separate modules each in a different processor.

### DRAWINGS

FIG. 1 depicts an exemplary generic TCPIP stack implemented in a multi-processor environment;

FIG. 2 depicts a first exemplary embodiment having multiple IP modules;

FIG. 3 depicts a second exemplary embodiment having IP modules with Bypass and Look-ahead-and-skip functionality that is dependent on the associated TCP connection state;

FIG. 4 depicts a third exemplary embodiment having both master and slave IP modules and master and slave TCP modules; and

FIG. 5 depicts yet another exemplary embodiment in which certain modules perform certain functionality of both a Network layer module and a Transport layer module.

### DETAILED DESCRIPTION

It should be understood that the intended audience for this specification will be familiar with conventional technology for transmitting and receiving digital information over the Internet (or other communications networks) and with the various standards and protocols that are commonly used for such transmissions such as “TCP” and “IP”, and will be familiar with the technical jargon commonly used by those skilled in the art to describe such technology. Accordingly, unless otherwise clear from their respective context, it should be assumed that the words and phrases in this description and in the appended claims are used in their technical sense as they would be understood by those skilled in the art.

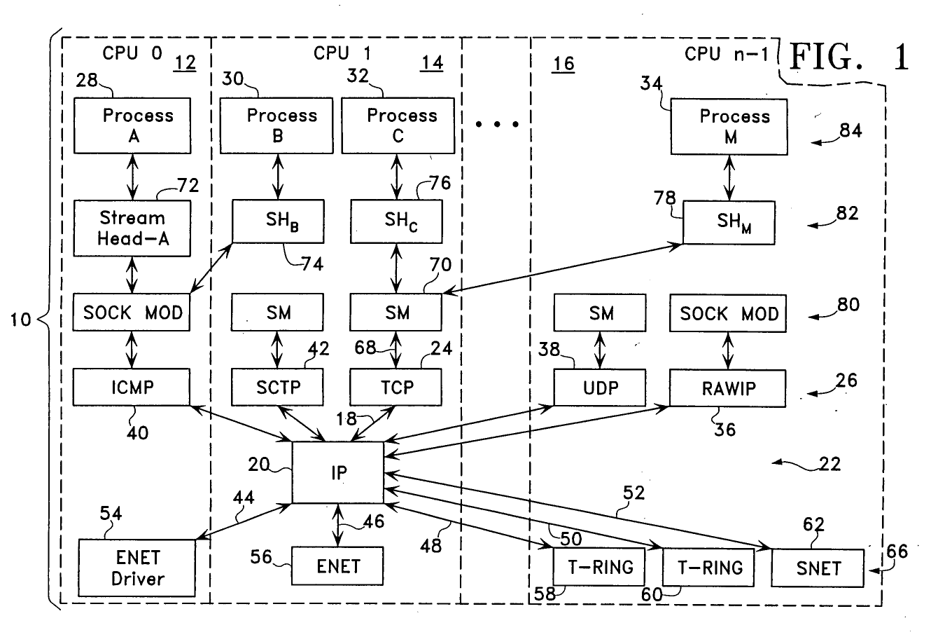

Reference should now be made to FIG. 1, which depicts a generic communications stack 10 implemented in a multi-processor environment comprising n processors CPU₁ 12, CPU₁ 14, ***, CPUₙ₋₁ 16. In particular, since there is only one IP/TCP processing thread 18 from the single IP module 20 in Network layer 22 to the single TCP module 24 in Transport layer 26, the CPU (e.g., CPU₁ 14) associated with that thread will have only limited available computing resources. It has been found that in a typical multiprocessor environment with at least 8 processors 12,14,16, the single IP module 20 and its associated single IP/TCP processing thread 18 will often consume all those available computing resources and many, perhaps all, of the associated TCP-based application processes 32,34 will be starved for data, even when data is indeed available at the Physical layer 66. IP layer 22 typically is linked to 5 associated Transport modules in Transport layer 26: RAWIP 36, TCP 24, UDP 38, ICMP 40, and SCTP 42. In one specific example with 32 processors 14,16 running 20 TCP processes 32,34 and the IP/TCP thread 18 running on a CPU 14 which is 100% busy, since the IP/TCP path is single threaded for TCP transport, the other processors 16 on which the TCP-based processes are running will be starved for data that is already in IP queues 44,46,48,50,52 associated with respective drivers 54,56,58,60,62 of Physical layer 66. Each protocol in Protocol layer 80 will typically have only one associated Socket Module, thus a similar data starvation may also result from the single thread 68 from TCP 24 to its associated socket compatibility module (“SOCKMOD”) 70. Moreover, even though there is a separate Stream Head 72,74,76,78 for each application process (file descriptor) 28,30,32,34, so the interface between the SOCKMOD 70 and the associated Application processes 32,34 is not necessarily single-threaded (e.g., the two threads associated with TCP Stream Heads 76,78), the previously described bottlenecks (e.g., within CPU₁ 14) in the lower layers 66,22,26,80 will necessarily have adverse effects even though additional computational resources (e.g., CPUₙ₋₁ 16) may be available at the upper layers 82,84. Note that communication typically is a bidirectional process, and that received messages will traverse the stack 10 from bottom 66 to top 84, while transmitted messages will traverse the stack from top 84 to bottom 66.

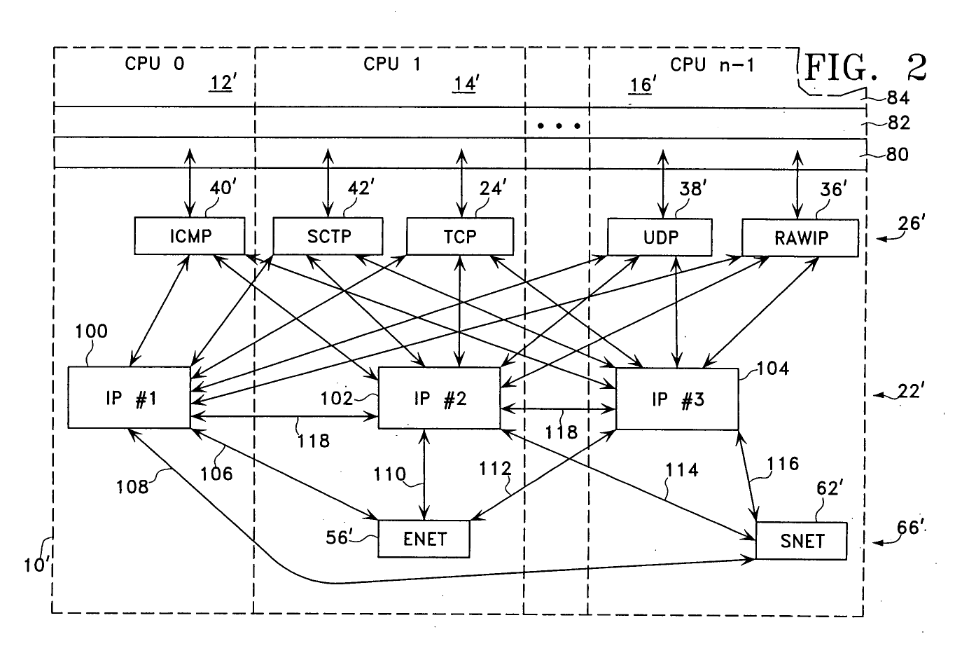

Reference should now be made to FIG. 2, which depicts a multi-processor embodiment having a first IP module 100 and additional IP modules 102,104, each running on a different CPU 12′, 14′, 16′ (the prime symbol signifies a modified version of a previously depicted element). At least one of the depicted IP modules (for example first IP module 100) functions as a high reliability, high availability supervisory entity to establish new logical IP connections with other networked devices, to perform IP control management functions such as error handling and statistics gathering, and to tear down logical IP connections that are no longer needed. Some or all of the IP modules (for example second and third IP modules 102, 104) provide routine handling of subsequent Data messages associated with the previously established logical IP connections. If certain modules (e.g., first IP module 100) are dedicated to supervisory functions and other modules (e.g., additional IP modules 102,104) are dedicated to routine functions under the control of those supervisory modules, each supervisory module is called a “master”, the other modules are called “slaves”, and the resultant configuration is known as a “Master/Slave” arrangement. Conversely, if each module 100,102,104 is capable of performing all the functionality required for a particular logical connection within a particular level of the communications stack 10′, then each such module is called a “peer” and the resultant configuration is known as a “distributed peer” arrangement.

In the master/slave configuration, once a new logical IP connection has been established by the first IP module 100, all subsequent Data messages (both incoming and outgoing) may be routed to another IP module 102, 104 associated with that connection, thereby taking advantage of the other available processing resources (multiple CPU's 14′, 16′) and data processing is less likely to be starved by a bottleneck within the network layer 22′ of the communications stack 10′.

An exemplary pseudo code to implement a simple version of this master/slave IP functionality could be as set forth in the appended Table 1:

TABLE 1

If Data message then send to IP slaves
Else send to master.

An alternative embodiment has one or more of the slave IP modules 102,104 in the other CPU's 14,16 configured as a hot backup master module for increased reliability. In other alternative embodiments, the master IP functionality may be distributed among multiple IP modules 100′, 102′, 104′ involving more than one CPU 12′, 14′, 16′ based on some readily ascertainable criterion such as Transport type 40,42,24,38,36, to thereby provide higher availability.

For incoming messages, the routing of a logical connection to a particular IP module 100,102,104 and associated CPU 12′, 14′, 16′ may be performed at the receiving node of the Physical layer, for example in the modified Ethernet driver 56′ associated with a particular network interface board and can be based for example on the Transport type and Transport address information contained in the IP message header, in accordance with an association table that is maintained by the IP Master module 100 and that is replicated in each of the network interface drivers 56′, 62′. The individual IP Slave modules 102,104 perform basic Data message processing, such as buffering and defragmentation, before the assembled Data message is forwarded to the appropriate module 40′, 42′, 24′, 38′, 36′ of the Transport layer 26′. Another copy of that same association table may also be replicated in the Transport level modules 40′, 42′, 24′, 38′, 36′ for routing outgoing Data messages to the particular IP Slave module 102,104 assigned to its associated IP connection.

In the Distributed Peer configuration, each IP module 100,102,104 has both Master and Slave functionality and control path 118 is provided for coordination of their supervisory activities. In particular, each IP module may be kept aware not only of any changes in the logical connection assignments made by its peer IP modules, but also of the respective processing loads for those peer IP modules. When a new (or unrecognized) connection request is received from an adjacent level (for example at ENET module 56′ or at TCP module 24′), it may be routed to any available IP module capable of functioning as an IP Master module, which validates and assigns the new connection to an appropriate IP module having IP Slave functionality (which could be the same IP module, or a different IP module) and updates the various routing tables in the IP layer 22′ and in the adjacent layers 66′, 26′. In such a distributed peer configuration (or other configurations with more than one available IP master) both the initial routing of the new connection request for validation, as well as the updating of the routing tables to include a particular IP module, can be a random process (for example, a simple round robin method) or driven by a defined policy (for example, based on available processing power and communications bandwidth of the various CPU's and other associated resources). In other alternative embodiments, the new connection is routed to all IP modules, which then coordinate among themselves over control path 118 to determine which IP module will be responsible for managing all Network layer processing for that particular connection, Such an alternative embodiment has the advantage that the outer layers do not have to be informed of the current processing capabilities of each of the Network layer modules.

In the depicted example, ENET network driver interface 56′ and SNET (server net) network driver interface 62′ each have a respective direct path 106,108 to first IP module 100. In the master/slave configuration, first IP module 100 is an IP Master module, and those paths are used only for Control messages. Ordinary Data messages are routed by ENET interface 56′ and SNET interface 62′ via respective paths 110,112,114,116 to their respective assigned slave IP modules 102,104. ENET 56′ (Physical layer 66′) and TCP 24′ (Transport layer 26′) for example, simply need to have additional logic or a routing table to determine which IP module gets what messages, because they are disposed within communication stack 10′ directly above or below the Network Layer 22′. Although not explicitly shown, other Physical layer interfaces such as Token Ring 58,60, or other ENET nodes 54 such as included in FIG. 1 (but modified to contain analogous replicated routing logic and/or routing tables) can also be supported. In the example depicted in FIG. 2, there is only one Transport level module for each transport type (for example TCP module 24′), which may be conventional except for the inclusion of routing logic and routing tables analogous to that in the modified ENET interface 56′. Accordingly, the Sock Mod layer 80, Stream Head layer 82 and Application layer 84 may be essentially unchanged from that previously described with reference to FIG. 1.

Note that communication of control information may occur both within the same level (for example, over horizontal path 118) and also between layers (for example, over vertical path 106). In particular, if there is a routing change in one layer (for example, if a particular processing module in one layer is no longer associated with a particular connection), then the surround context (routing tables) in the upper and lower layers may also get affected, and if there is an unexpected state change (for example, if a particular processing module in one layer is no longer available) then any master or peer module in the affected layer should be informed of that state change.

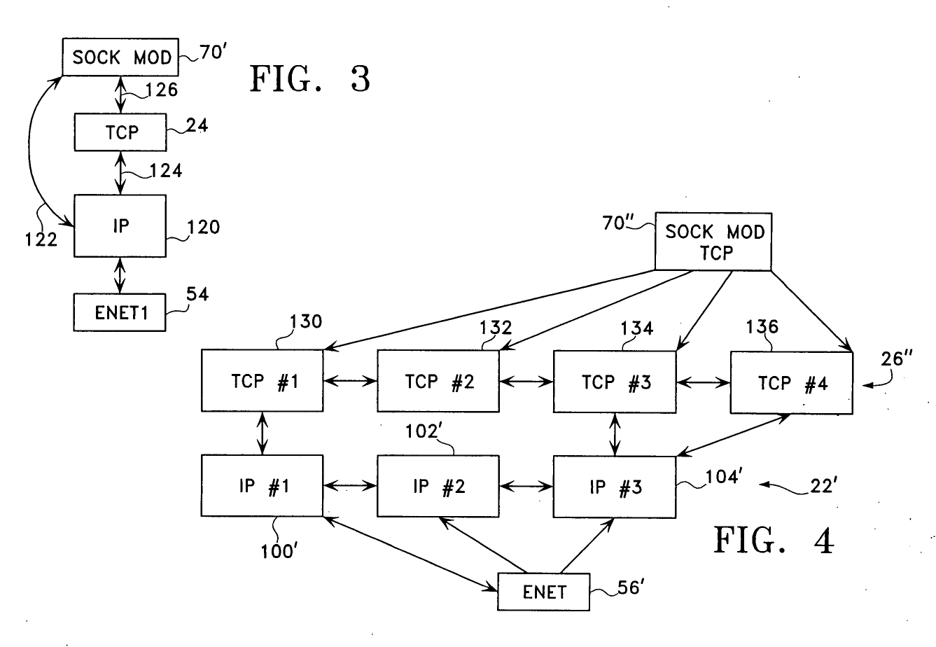

Reference should now be made to FIG. 3, which depicts a second exemplary embodiment having an enhanced IP module 120 with Bypass functionality for the particular case in which the IP module 120 has been informed that the designated Transport layer module (for example TCP module 24) is not currently processing any messages for a particular connection for which that Transport layer module is responsible. In that case, the enhanced IP module 120 responsible for the connection simply queues the messages directly to the designated SOCKMOD 70′ via Bypass path 122 after performing any required basic Transport layer processing (for example, verification that the message is complete and that all prior messages have already been processed). Conversely, as indicated by Direct connection 124 between IP module 120 and TCP module 24 and Direct connection 126 between TCP module 24 and its designated SOCKMOD 70′, if more complex Transport layer processing is required than can be accommodated in the enhanced IP module 120 (for example, a received message has errors that cannot be corrected, or is received out of sequence), the message is forwarded to the appropriate Transport layer module, for example TCP module 24.

In the latter case, a “TCP_empty” flag should be reset in the enhanced IP module 120 to indicate that a previous message for a particular connection has been queued to TCP 24 for some reason, and the current state of the TCP module 24 should be checked before any subsequent TCP messages are queued directly to SOCKMOD 70′ over Bypass path 122, so that all subsequent TCP messages are given to TCP module 24 until the TCP module is able to handoff at least basic responsibility for TCP message processing back to the enhanced IP module 120. Thus, at least some scheduler overhead, queuing, and latency may be avoided if such a skip method has been implemented in an adjacent layer (e.g., in a modified version of IP layer 22 for incoming messages, and in a modified version of SOCKMOD layer 80 for outgoing messages), assuming that at least rudimentary Transport layer 26 functionality and any required connection look up tables that would normally be present in the TCP module 24 are replicated in the involved adjacent-level modules 120,70′. As an additional refinement, the “TCP_empty” flag can be supplemented with a “Look_ahead_and_skip” flag to distinguish the case where the TCP module 24 is performing critical Transport layer processing (for example, a TCP Control message) that must be completed before the application layer can process any Data (TCP_empty =1, Look_ahead_and_skip=0) from the case where there is simply a backlog in the TCP module (TCP_empty=1, Look_ahead_and_skip=1). In that latter case, it would be possible to assign additional resources to the TCP module 24, or to reassign its pending or future workload, or even to hold any subsequently received Data messages in the Network layer 22 until the backlog in the Transport layer 26 is cleared and the held Data messages can be released directly to the SOCKMOD 70′ and thereby skipping the Transport layer altogether. Thus, when the TCP determines that there is no remaining such critical (or error or other non-normal) message processing that it needs to do, it may simply assign normal messages to an adjacent layer module (for example, SOCKMOD or IP) and set both TCP_empty and Look_ahead_and_skip to “1”. Those settings allow the processing of normal messages to be performed in an adjacent layer, thereby bypassing the TCP module in the Transport layer. In other words, rather than handing off the message to the TCP layer, the corresponding module in the adjacent lower layer hands off the message directly to an appropriate module in an adjacent higher layer, with the minimal TCP processing required for such normal messages being performed in one of those surrounding layers.

An exemplary pseudo code to implement a simple version of this TCP Bypass and Look Ahead functionality could be as set forth in the appended Table 2:

Reference should now be made to FIG. 4, which depicts a third exemplary embodiment with not only multiple IP modules 100′, 102′, 104′ but also multiple TCP

TABLE 2

If TCP_empty = 0, QUEUE message to TCP
Else if Data message and look-ahead_and_skip = 1
(most of the time this case only!)

SKIP TCP and its state processing

Else if Data message and look_ahead_and_skip = 0

QUEUE message to TCP
RESET TCP_empty = 0

Else if Control message

QUEUE message to TCP,
RESET TCP_empty = 0
RESET look-ahead-skip = 0

After Data message has been processed by TCP:

UPDATE TCP_empty

After Control message has been processed by TCP:

UPDATE look_ahead_and_skip and TCP_empty.

modules 130,132,134,136. As previously discussed with reference to FIG. 2, the individual modules in a particular layer may be configured either in a Master/Slave configuration or in a Distributed Peer configuration. In either case, parallel communication module functionality similar to that employed in the Network layer 22 of the FIG. 2 embodiment, including analogous routing and lookup tables, can also be provided in the TCP transport layer 26″, distributed among multiple TCP modules 130,132,134,136, which may include one or more such modules with Master functionality, one or more with Slave functionality, and/or one or more modules with both Master and Slave functionality. In the particular case of a Master/Slave TCP configuration, each of the other TCP modules 132,134,136 may have its local replicated copy of the routing and connection tables maintained by master TCP module 130, which may also provide a subset of those tables to the IP modules 100′, 102′, 104′ in the Network layer 22, so that each incoming Data message of a particular TCP connection is routed to a designated TCP module 132,134,136 (if a particular slave TCP module has already been assigned to that connection) or to the Master TCP module 130 (if no TCP slave module has been assigned). Alternatively, the involved IP slave module 104′ can be instructed by master IP module 100′ to queue a received TCP message to a second slave TCP module 136 in the event the first slave TCP module 134 is busy or otherwise unavailable. Similarly, if a master TCP module 130 detects a possible failure in the first slave TCP module 134 which it has assigned to a particular TCP connection, it may reassign that connection to second TCP slave module 136. If the error is recoverable and the involved data is still available, the second slave module may be instructed to initiate retransmission of the last acknowledged message that was successfully received and acknowledged by the failed TCP module 132 and of any subsequently transmitted messages that have not been so acknowledged. If the error is not recoverable or the involved data is not still available, then the connection is reset and any doubtful data is retransmitted. In any event, in this particular embodiment there is only one TCP SOCKMOD 70″ that receives all the TCP messages from all instances of TCP slaves 132,134,136 and TCP master(s) 130 (and also directly from the IP modules 100′, 102′, 104′, if the Bypass capability of FIG. 3 has been implemented).

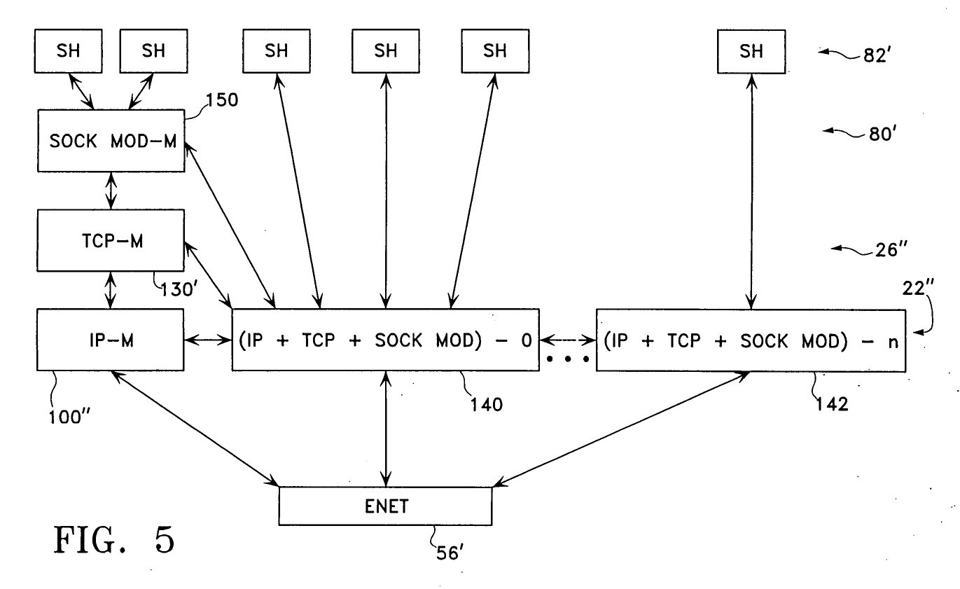

FIG. 5 depicts yet another exemplary embodiment in which certain IP modules 140,142 are “consolidated” with all of the functionality of both a Network layer IP module 102′, 104′ and a Transport layer TCP module 132,134,136, for rationalizing and thereby reducing the required processing for a related set of TCP connections (for example, for all the connections associated with the processes performed by a specific CPU). As illustrated at least the routine IP, TCP and SOCKMOD “slave” functionalities are consolidated in each consolidated slave module 140,142 and the consolidated modules are replicated to thereby provide parallelism not only in the IP layer 22″ and TCP layer 26″, but also in the SOCKMOD layer 80′, with a rationale and grouping that does not result in an excessive number of such consolidated modules and that can be dynamically updated to reflect changes in usage. As discussed in connection with the other embodiments, a dynamic routing mechanism may be provided (for example, in master IP module 100″) for advising the surrounding context (for example, the ENET physical layer driver 56′) concerning the current processing assignments for all the active connections.

As was true for a master/slave implementation of the embodiment of FIG. 4, in FIG. 5 Master IP module 100″ and master TCP module 130′ (together with master Sock Mod module 150 ) may process Control messages and any unroutable Data messages. Moreover, consolidated slave modules 140,142, may be provided with empty and look-ahead-and-skip flags to thereby avoid unnecessary processing when there is no state change for the involved connection. Moreover, since there is only one consolidated slave module 140 (instead of three unconsolidated modules 100″, 130′, 150) in the path from the ENET driver 56′ to the Stream Head layer 82″, queuing and thus latency is reduced, if not completely eliminated.

Thus, it becomes possible to increase throughput and to make better use of available resources by selective bypassing of certain communication layers and/or by consolidating some or all of those individual layers into a single process and/or by distributing one or more layers among multiple processors. Although the foregoing description has assumed that the individual processing modules in the communication stack are implemented as device drivers and other utility software running in respective general purpose CPU's in a multiprocessor host environment, many aspects of the disclosed invention will also be applicable to embodiments in which some or all of that functionality is performed by programmed logic arrays and other dedicated hardware, thereby offloading the involved communications processing from the host CPU's. Doubtless, other modifications and enhancements will be apparent to those skilled in the art. For example, some or all of the disclosed replication and/or consolidation of the layered communication stack functionality can be incorporated into the on-board processors of Ethernet boards and other hardware interfaces at the edges of the LAN, WAN, or other external communication network hardware. As another example, certain critical functions and hardware can be duplicated and operated in parallel to provide a more fault tolerant system, and other functions can be dynamically reassigned to different processors or other hardware to accommodate changing environments and user requirements. If for some set of connections, a real time response is required, hard or soft connections can be migrated or other processing loads from that processor set can be migrated as necessary to meet that real time performance requirement, possibly using connection tables and related data structures and process sets which are organized as pools of data structures.

What is claimed is:

1. A layered communication stack comprising at least first and second modules within the same layer for processing messages, wherein said first module is running on one processor of a multi-processor system, and said second module is running on a different processor of said system.

2. The communication stack of claim 1 further comprising a third module for processing control messages to determine which data messages are to be processed by each of said first and second modules.

3. The communication stack of claim 1 wherein both said first module and said second module are each capable of processing both control messages and data messages.

4. The communication stack of claim 1 herein the same layer is a network layer and at least some of said modules are IP modules.

5. The communication stack of claim 4 herein a plurality of said IP modules is connected to at least one common transport module in a transport layer above said network layer and to at least one common driver module in a physical layer below said network layer.

6. The communication stack of claim 5 wherein each of said plurality of said IP modules is connected to different types of transport modules in a transport layer above said network layer and to different types of driver modules in a physical layer below said network layer.

7. The communication stack of claim 6 wherein each of said plurality of said IP modules is connected to each of said transport modules.

8. The communication stack of claim 6 wherein each of said plurality of said IP modules is connected to each of said driver modules.

9. The communication stack of claim 1 wherein the same layer is a transport layer and at least some of said modules are TCP modules.

10. The communication stack of claim 9 wherein each of said TCP modules is connected to at least one common TCP socket compatibility module in a Sock Mod layer above said transport layer and to at least one IP module in a network layer below said transport layer.

11. The communication stack of claim 10 wherein more than one of said TCP modules is connected to a common said IP module.

12. A layered communication stack of claim 1 wherein a communication module in a first layer is provided with limited functionality from an adjacent layer and with means for selectively bypassing that adjacent layer.

13. The communication stack of claim 12 wherein said adjacent layer is a transport layer, an IP module in a network layer below the transport layer includes a first subset of TCP functionality from a TCP module in the transport layer, a socket compatibility module in a SockMod layer above the transport layer includes a second subset of TCP functionality from said TCP module, and said IP module and said socket compatibility module selectively bypass said TCP module only when no TCP functionality is required in addition to said first and second subsets of TCP functionality.

14. The communication stack of claim 13 wherein the functionality of each of at least the first and second modules includes IP network layer functionality, TCP transport layer functionality, and associated socket compatibility module functionality.

15. A method for increasing throughput in a layered communication stack comprising the step of providing within a same layer of the communication stack a plurality of a same type of processing modules each running on a different CPU of a multiprocessor host computer.

16. The method of claim 15 wherein the same type of processing modules are slave processing modules for processing data messages and said method further comprises the step of providing a master processing module for controlling said slave processing modules in response to control messages.

17. The method of claim 15 wherein the layer is a network layer and said processing modules are IP modules.

18. The method of claim 15 wherein the layer is a transport layer and said processing modules are transport layer modules.

19. The method of claim 15 further comprising the step of consolidating slave processing modules in respective adjacent layers of the communication stack.

20. The method of claim 19 wherein the adjacent layers include a network layer and a transport layer and the consolidated processing modules include IP modules and TCP modules.

21. The method of claim 15 further comprising the steps of providing a module in a first layer with limited functionality from a module in a second layer and selectively bypassing the module in the second layer.

22. The method of claim 19 wherein the first layer is a network layer, the second layer is a transport layer and the limited functionality is a subset of the functionality of a TCP module.

23. The method of claim 19 wherein the first layer is a SockMod layer, the second layer is a transport layer and the limited functionality is a subset of the functionality of a TCP module.

24. A networked data processing system comprising:
a plurality of computer processing units configured as a single multiprocessor host computer;
a plurality of applications running on said host, not all of the applications running on a same one of the computer processing units;
a plurality of network modules, each running on a different one of said computer processing units;
a common network driver module for connecting said multiprocessor host computer to an external network;
first means for routing data messages between the common network driver and each of the network modules; and
second means for routing data messages between each of the network modules and each of the applications.

25. The networked data processing system of claim 24 wherein the first means includes a shared routing table accessible to each said network driver.

26. The networked data processing system of claim 24 wherein the second means includes at least one transport module running on said host.

27. The networked data processing system of claim 24 wherein the second means includes a plurality of TCP transport modules each running on a different one of said computer processing units, a shared TCP Socket Compatibility Module, and a plurality of Stream Head modules each associated with a respective one of said applications.

28. The networked data processing system of claim 24 wherein the network modules include multiple IP modules in a network layer of a layered communication stack.

29. The networked data processing system of claim 28 wherein one of said IP modules is configured as a master IP module, and others of said IP modules are configured as slave IP modules controlled by the master IP module.

30. The networked data processing system of claim 28 wherein all of said IP modules have the same functionality and are each capable of processing both Control messages and Data messages.
